(19) United States
(12) Patent Application Publication
(10) Pub. No.: US 2026/0150571 A1
(43) Pub. Date: May 28, 2026

(54) DISPLAY DEVICE

(71) Applicant: LG Display Co., Ltd., Seoul (KR)

(72) Inventors: SangHoon OH, Seoul (KR); HyeongMin JEON, Goyang-si (KR); Heeyeon HWANG, Hanam-si (KR)

(73) Assignee: LG Display Co., Ltd., Seoul (KR)

(21) Appl. No.: 19/345,542

(22) Filed: Sep. 30, 2025

(30) Foreign Application Priority Data
Nov. 28, 2024 (KR) 10-2024-0173296

(51) Int. Cl. H10K 59/80; H10H 29/01; H10H 29/49; H10H 29/855; H10K 59/12; H10K 59/131; H10K 102/00

(52) U.S. Cl. CPC H10K 59/8793; H10H 29/012; H10H 29/49; H10H 29/8552; H10K 59/1201; H10K 59/131; H10K 59/8792; H10K 2102/311

(57) ABSTRACT

A display device can include a lower substrate having a plurality of rigid areas and a malleable area enclosing the plurality of rigid areas, a plurality of first plate patterns disposed on the plurality of rigid areas of the lower substrate, a plurality of light emitting diodes disposed on the plurality of first plate patterns, and a polarization plate disposed on the plurality of light emitting diodes and including a plurality of polarization patterns and a black pattern enclosing the plurality of polarization patterns. The polarization patterns overlap the rigid areas and the black pattern overlaps the malleable area. Accordingly, the polarization plate having a black pattern is formed to improve the outdoor visibility and improve the black luminosity.

### CROSS-REFERENCE TO RELATED APPLICATIONS

This application claims priority to Korean Patent Application No. 10-2024-0173296, filed on Nov. 28, 2024, in the Republic of Korea, the entire disclosure of which is hereby expressly incorporated by reference.

### BACKGROUND

### Field

The present disclosure relates to a display device, and more particularly to a stretchable display device which can be stretched.

### Description of the Related Art

Among display devices which are used for a monitor of a computer, a television, or a cellular phone, there can be an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Recently, a display device, which is manufactured by forming a display unit and a wiring line on a flexible substrate such as plastic being a flexible material so as to be stretchable in a specific direction and changed in various forms, is getting attention as a next generation display device.

### SUMMARY OF THE DISCLOSURE

An object to be achieved by the present disclosure is to provide a stretchable display device which reduces reflection of external light.

Another object to be achieved by the present disclosure is to provide a stretchable display device with an improved outdoor visibility.

Still another object to be achieved by the present disclosure is to provide a stretchable display device with an improved black luminosity.

Another object to be achieved by the present disclosure is to provide a stretchable display device including a stretchable polarization plate.

Still another object to be achieved by the present disclosure is to provide a stretchable display device including a polarization plate in which deformation of a polarization pattern during the stretching is minimized.

Objects of the present disclosure are not limited to the above-mentioned objects, and other objects, which are not mentioned above, can be clearly understood by those skilled in the art from the following descriptions.

According to an aspect of the present disclosure, a display device includes a lower substrate which includes a plurality of rigid areas and a malleable area enclosing each of the plurality of rigid areas; a plurality of first plate patterns disposed in the plurality of rigid areas of the lower substrate; a plurality of light emitting diodes disposed on the plurality of first plate patterns; and a polarization plate which is disposed on the plurality of light emitting diodes and includes a plurality of polarization patterns and a black pattern which encloses the plurality of polarization patterns. The plurality of polarization patterns overlaps the plurality of rigid areas and the black pattern overlaps the malleable area. Accordingly, the polarization plate having a black pattern is formed to improve the outdoor visibility and improve the black luminosity.

Other detailed matters of the example embodiments of the present disclosure are included in the detailed description and the drawings.

According to aspects of the present disclosure, a polarization plate is embedded in the display device to minimize external light reflection.

According to aspects of the present disclosure, a polarization plate is embedded in the display device to improve outdoor visibility.

According to aspects of the present disclosure, a polarization plate includes a black pattern to improve a black luminosity of the display device.

According to aspects of the present disclosure, a polarization pattern and a black pattern are separated to minimize deformation of the polarization pattern during the stretching.

The effects according to aspects of the present disclosure are not limited to the contents exemplified above, and other various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic cross-sectional view of a display device according to an example embodiment of the present disclosure;

FIG. 2 is a plan view of a display device according to an example embodiment of the present disclosure;

FIG. 3 is a schematic enlarged plan view of an area A illustrated in FIG. 2;

FIGS. 4 to 6 are cross-sectional views taken along line IV-IV′ of FIG. 3;

FIGS. 7A to 7F are process diagrams for explaining a manufacturing method of a display device according to an example embodiment of the present disclosure;

FIG. 8 is a schematic cross-sectional view of a display device according to another example embodiment of the present disclosure; and

FIGS. 9A to 9F are process diagrams for explaining a manufacturing method of a display device according to another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components. Therefore, a first component to be mentioned below can be a second component in a technical concept of the present disclosure. Further, the term “can” fully encompasses all the meanings and coverages of the term “may” and vice versa.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings. All the components of each display device/apparatus according to all embodiments of the present disclosure are operatively coupled and configured.

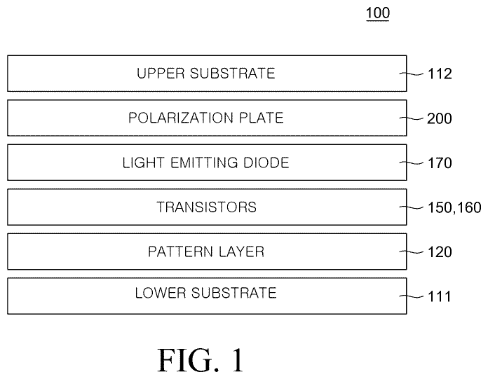

FIG. 1 is a schematic cross-sectional view of a display device according to an example embodiment of the present disclosure.

First, a display device 100 according to an example embodiment of the present disclosure is a display device 100 which is capable of displaying images even in a bent or extended state and can also be referred to as a stretchable display device, a flexible display device and an extendable display device. As compared with the general display devices of the related art, the display device 100 can have not only a high flexibility, but also stretchability. Therefore, the user can bend or extend a display device 100 and a shape of a display device 100 can be freely changed in accordance with manipulation of a user. For example, when the user pulls the display device 100 by holding ends of the display device, the display device 100 can be extended to the pulling direction of the user. Alternatively, when the user disposes the display device 100 on an outer surface which is not flat, the display device 100 can be disposed to be bent in accordance with the shape of the outer surface of the wall. Further, when a force applied by the user is removed, the display device 100 can return to its original shape.

Referring to FIG. 1, the display device 100 according to the example embodiment of the present disclosure includes a lower substrate 111, a pattern layer 120, transistors 150 and 160, a light emitting diode 170, a polarization plate 200, and an upper substrate 112.

The lower substrate 111 and the upper substrate 112 are members which support and protect other configurations of the display device 100. The light emitting diode 170 can emit light in response to the control of the transistors 150 and 160 so that an image can be displayed on a front surface of the display device 100. The polarization plate 200 suppresses external light reflection to improve the visibility of the display device 100.

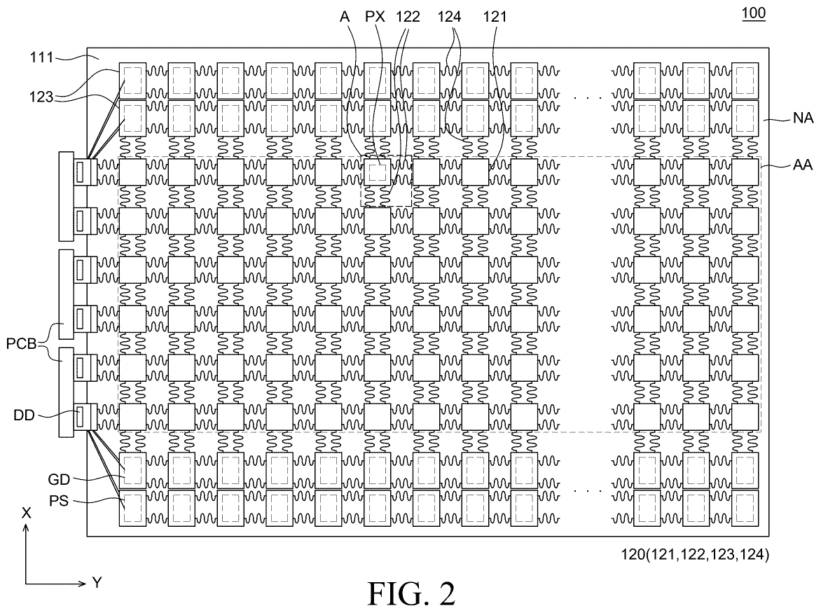

Hereinafter, the display device 100 according to the example embodiment of the present disclosure will be described in detail with reference to FIGS. 2 to 4.

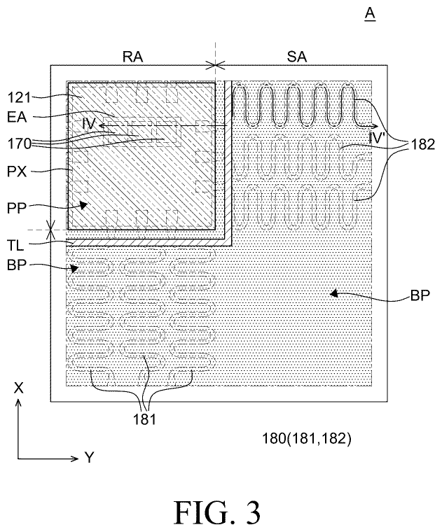

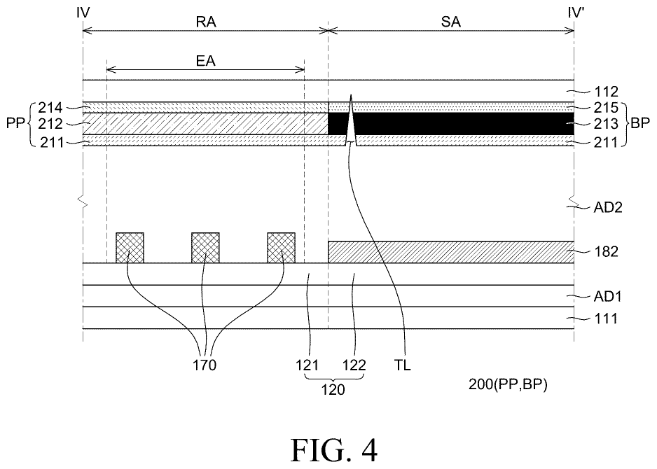

FIG. 2 is a plan view of a display device according to an example embodiment of the present disclosure. FIG. 3 is a schematic enlarged plan view of an area A illustrated in FIG. 2. FIGS. 4 to 6 are cross-sectional views taken along line IV-IV′ of FIG. 3.

Referring to FIGS. 2 to 4, the lower substrate 111 supports various components of the display device 100 and the upper substrate 112 can cover various components of the display device 100.

The lower substrate 111 and the upper substrate 112 which are flexible substrates can be configured by an insulating material which is bendable or extendable. For example, the lower substrate 111 and the upper substrate 112 can be formed of a silicon rubber such as polydimethylsiloxane (PDMS) or an elastomer such as polyurethane (PU) or polytetrafluoroethylene (PTFE) and thus have a flexibility. Further, the materials of the lower substrate 111 and the upper substrate 112 can be the same, but are not limited thereto and can vary.

The lower substrate 111 and the upper substrate 112 are flexible substrates so as to be reversibly expandable and contractible.

The lower substrate 111 can include an active area AA in which images are displayed and a non-active area NA excluding the active area AA. The active area AA is an area in which images are displayed in the display device 100. Components for driving the plurality of pixels PX disposed in the active area AA are disposed in the non-active area NA. For example, in the active area AA, a plurality of pixels PX is disposed and in the non-active area NA, a gate driver GD and a power supply PS can be disposed.

The lower substrate 111 can also be defined to include a plurality of rigid areas RA and malleable areas SA. The plurality of rigid areas RA can be disposed to be spaced apart from each other. The plurality of rigid areas RA can be areas of the lower substrate 111 overlapping the plurality of first plate patterns 121 and the plurality of second plate patterns 123. The plurality of rigid areas RA can be areas in which the plurality of first plate patterns 121 and the plurality of second plate patterns 123 are disposed to have a rigidity.

The malleable area SA can be an area which encloses each of the plurality of rigid areas RA. The malleable area SA can be an area which does not overlap the plurality of first plate patterns 121 and the plurality of second plate patterns 123. The malleable area SA is an area between the plurality of first plate patterns 121 and the plurality of second plate patterns 123 and can include an area in which the plurality of first line patterns 122 and the plurality of second line patterns 124 are disposed. Further, the malleable area SA can include an area in which the pattern layer 120 is not disposed. The malleable area SA can be an area in which the plurality of first plate patterns 121 and the plurality of second plate patterns 123 are not disposed to be flexibly deformable.

Accordingly, in the plurality of rigid areas RA, the plurality of first plate patterns 121 and the plurality of second plate patterns 123 are disposed and in the malleable area SA, the plurality of first plate patterns 121 and the plurality of second plate patterns 123 are not disposed so that the plurality of rigid areas RA can be more rigid than the malleable area SA.

In the meantime, the active area AA, the non-active area NA, the malleable area SA, and the plurality of rigid areas RA are not mentioned to be limited to the lower substrate 111, but can be mentioned for the overall display device 100.

Next, the pattern layer 120 is disposed on the lower substrate 111. The pattern layer 120 includes a plurality of first plate patterns 121 and a plurality of first line patterns 122 disposed in the active area AA and a plurality of second plate patterns 123 and a plurality of second line patterns 124 disposed in the non-active area NA.

The plurality of first plate patterns 121 and the plurality of second plate patterns 123 can be substrates on which configurations, such as the pixel PX, the gate driver GD, and the power supply PS are formed. The plurality of first plate patterns 121 and the plurality of second plate patterns 123 can be disposed in the form of separate islands. The plurality of first plate patterns 121 and the plurality of second plate patterns 123 are spaced apart from each other to be disposed on the lower substrate 111. For example, the plurality of first plate patterns 121 and the plurality of second plate patterns 123 can be disposed in a matrix, but are not limited thereto. In the meantime, even though in FIG. 2, it is illustrated that the plurality of first plate patterns 121 and the plurality of second plate patterns 123 have a rectangular shape, the shape thereof is not limited thereto.

The plurality of first line patterns 122 connects first plate patterns 121 which are adjacent to each other and the plurality of second line patterns 124 can connect a first plate pattern 121 and a second plate pattern 123 which are adjacent to each other or a plurality of second plate patterns 123 which is adjacent to each other. The plurality of first line patterns 122 and the plurality of second line patterns 124 can have a wavy shape, for example, a sine wave shape, but are not limited thereto.

The plurality of first plate patterns 121, the plurality of first line patterns 122, the plurality of second plate patterns 123, and the plurality of second line patterns 124 can be rigid patterns. For example, the plurality of first plate patterns 121, the plurality of first line patterns 122, the plurality of second plate patterns 123, and the plurality of second line patterns 124 can be more rigid than the lower substrate 111 and the upper substrate 112. Accordingly, moduli of elasticity and hardness of the plurality of first plate patterns 121, the plurality of first line patterns 122, the plurality of second plate patterns 123, and the plurality of second line patterns 124 can be higher than a modulus of elasticity and the hardness of the lower substrate 111. For example, moduli of elasticity of the plurality of first plate patterns 121, the plurality of first line patterns 122, the plurality of second plate patterns 123, and the plurality of second line patterns 124 can be 1000 times higher than the moduli of elasticity of the lower substrate 111 and the upper substrate 112, but it is not limited thereto.

The plurality of first plate patterns 121, the plurality of first line patterns 122, the plurality of second plate patterns 123, and the plurality of second line patterns 124 can be formed of a plastic material having a lower flexibility than the lower substrate 111 and the upper substrate 112.

Referring to FIGS. 2 and 3, a pixel PX including the plurality of sub pixels is disposed on the plurality of first plate pattern 121. Each of the plurality of sub pixels can include a light emitting diode 170 and a circuit for driving the light emitting diode 170.

The plurality of pixels can be connected to the plurality of connection lines 180. For example, the plurality of pixels can be electrically connected to a first connection line 181 extending in the first direction X and a second connection line 182 extending in the second direction Y.

Referring to FIG. 2, the gate driver GD can be mounted on the plurality of second plate patterns 123. The gate driver GD is a component which supplies a gate voltage to the plurality of pixels PX disposed in the active area AA. For example, the gate driver GD includes a plurality of stages formed on the plurality of second plate patterns 123 and each stage of the gate driver GD can be electrically connected to each other by means of the plurality of connection lines 180. Accordingly, a gate voltage output from any one of stages can be transmitted to the other stage. Further, each stage can sequentially supply the gate voltage to the plurality of pixels PX connected to each stage.

The power supply PS can be mounted in the plurality of second plate patterns 123. The power supply PS can be electrically connected to the gate driver GD and the plurality of pixels PX. For example, the power supply PS can supply a gate driving voltage and a gate clock voltage to the gate driver GD. Further, the power supply PS is connected to the plurality of pixels PX to supply a pixel driving voltage to each of the plurality of pixels PX.

The printed circuit board PCB includes a controller, such as an IC chip or a circuit unit and/or a memory or a processor to transmit a signal and a voltage for driving the display element from the controller to the display element. The printed circuit board PCB can include a stretching area and a non-stretching area to ensure stretchability. For example, in the non-stretching area, an IC chip, a circuit unit, a memory, and a processor can be mounted and in the stretching area, wiring lines which are electrically connected to the IC chip, the circuit unit, the memory, and the processor can be disposed.

The data driver DD is a component which supplies a data voltage to the plurality of pixels PX disposed in the active area AA. The data driver DD is configured as an IC chip so that it can also be referred to as a data integrated circuit D-IC.

Referring to FIG. 4, a first adhesive layer AD1 is disposed between the lower substrate 111 and the pattern layer 120. The first adhesive layer AD1 can adhere the lower substrate 111 and the pattern layer 120. For example, the first adhesive layer AD1 can be an optically clear adhesive (OCA) and can be configured by an acrylic-based adhesive, a silicon-based adhesive, and an urethane-based adhesive.

A plurality of light emitting diodes 170 is disposed on the plurality of first plate patterns 121. The light emitting diode 170 can be any one of a light emitting diode (LED) or a micro LED. However, an organic light emitting diode (OLED) is also used as the light emitting diode 170, but is not limited thereto. Each of the plurality of first plate patterns 121 includes an emission area EA in which the plurality of light emitting diodes 170 is disposed.

In the meantime, a plurality of circuits and a plurality of wiring lines for driving the plurality of light emitting diodes 170 can be disposed together on the plurality of first plate patterns 121. For example, the plurality of circuits can include an element, such as a driving transistor, a switching transistor, and a storage capacitor. For example, the plurality of wiring lines can include a gate line, a data line, a high potential voltage line, a low potential voltage line, and a reference voltage line, depending on the configuration of the circuit.

The connection line 180 is disposed on the plurality of first line patterns 122. The connection line 180 refers to a wiring line which electrically connects pads above the plurality of first plate patterns 121. Further, the connection line 180 can extend onto the plurality of first plate patterns 121 from the plurality of first line patterns 122 to be electrically connected to the pads on the plurality of first plate patterns 121. The first line patterns 122 is not disposed in an area where the connection lines 180 is not disposed, among areas between the plurality of first plate patterns 121.

The connection line 180 includes a first connection line 181 and a second connection line 182. The first connection line 181 and the second connection line 182 are disposed between the plurality of first plate patterns 121. Specifically, the first connection line 181 refers to a wiring line extending in a first direction X between the plurality of first plate patterns 121, among the connection lines 180. The second connection line 182 refers to a wiring line extending in a second direction Y between the plurality of first plate patterns 121, among the connection lines 180. For example, the connection line 180 can include various metal materials.

In the case of a general display device, various wiring lines such as a plurality of gate lines and a plurality of data lines extend between the plurality of sub pixels in a straight line and the plurality of sub pixels is connected to one signal line. Therefore, in the general display device, various wiring lines, such as a gate line, a data line, a high potential voltage line, and a reference voltage line, extend from one side to the other side of the display device without being disconnected on the substrate.

In contrast, in the display device 100 according to the example embodiment of the present disclosure, various wiring lines, such as a gate line, a data line, a high potential voltage line, a reference voltage line, and an initialization voltage line having a straight line shape which are considered to be used for the general display device, are disposed only on the plurality of first plate patterns 121 and the plurality of second plate patterns 123.

Further, in the display device 100 according to the example embodiment of the present disclosure, the pads on two adjacent first plate patterns 121 can be connected by the connection lines 180. For example, the gate line can be disposed on the plurality of first plate patterns 121 disposed to be adjacent to each other in the first direction X and the gate pad can be disposed on both ends of the gate line. At this time, the plurality of gate pads on the plurality of first plate patterns 121 adjacent to each other in the first direction X can be connected to each other by the first connection line 181. Therefore, the gate line disposed on the plurality of first plate patterns 121 and the first connection line 181 disposed on the first line pattern 122 can serve as one gate line.

Accordingly, among all various wiring lines which can be included in the display device 100, wiring lines which extend in the first direction X, such as an emission signal line, a low potential voltage line, and a high potential voltage line, can also be electrically connected by the first connection line 181, as described above. Further, the second connection line 182 can connect pads on the plurality of first plate patterns 121 which is disposed to be adjacent to each other in the second direction Y. For example, the second connection line 182 can connect pads of a data line, a high potential voltage line, a low potential voltage line, or a reference voltage line, but is not limited thereto.

A second adhesive layer AD2 which covers the front surface of the lower substrate 111 is disposed. The second adhesive layer AD2 can adhere the polarization plate 200 onto the lower substrate 111. The second adhesive layer AD2 can be filled in a space between the upper substrate 112 and the lower substrate 111. The second adhesive layer AD2 can be formed by coating and then curing a material which configures the second adhesive layer AD2 on the front surface of the lower substrate 111. For example, the second adhesive layer AD2 can be an optically clear adhesive (OCA) and can be configured by an acrylic-based adhesive, a silicon-based adhesive, and an urethane-based adhesive.

The upper substrate 112 is a substrate which supports various components disposed below the upper substrate 112. The upper substrate 112 can be disposed on the polarization plate 200. The upper substrate 112 is disposed so as to cover the polarization plate 200, the second adhesive layer AD2, the pattern layer 120, and the components on the pattern layer 120.

The polarization plate 200 is disposed between the second adhesive layer AD2 and the upper substrate 112. The polarization plate 200 can function to polarize light incident from the outside of the display device 100 to reduce the external light reflection. Further, the polarization plate 200 includes a black pattern to improve the black luminosity of the display device 100. The polarization plate 200 includes a plurality of polarization patterns PP, a black pattern BP which encloses the plurality of polarization patterns PP, and a tear line TL.

The polarization pattern PP is a configuration of reducing the external light reflection and can serve as a polarization plate 200. The polarization plate 200 is disposed on the plurality of light emitting diodes 170. The plurality of polarization patterns PP suppresses external light which is incident to the plurality of pixels PX from being reflected from various metal materials of the plurality of pixels PX to be directed to the outside again. The plurality of polarization patterns PP suppresses external light reflection to improve the visibility of the display device 100.

The plurality of polarization patterns PP can be disposed on the plurality of pixels PX. The plurality of polarization patterns PP can be disposed in the plurality of rigid areas RA in which the plurality of pixels PX is formed. When the display device 100 is stretched, the polarization pattern PP disposed in the rigid area RA is not deformed, but can maintain the same size. The plurality of polarization patterns PP is disposed to be spaced apart from each other and can be disposed in a matrix. The plurality of polarization patterns PP can be disposed so as to overlap the plurality of rigid areas RA. Each of the plurality of polarization pattern PP can be disposed so as to overlap at least the emission area EA in each of the plurality of first plate patterns 121. The polarization pattern PP can be formed to be larger than the emission area EA. The polarization pattern PP can be formed to have a size which is equal to or smaller than the rigid area RA. The size of the polarization pattern PP can be formed in the range of the size of the emission area EA and the size of the rigid area RA.

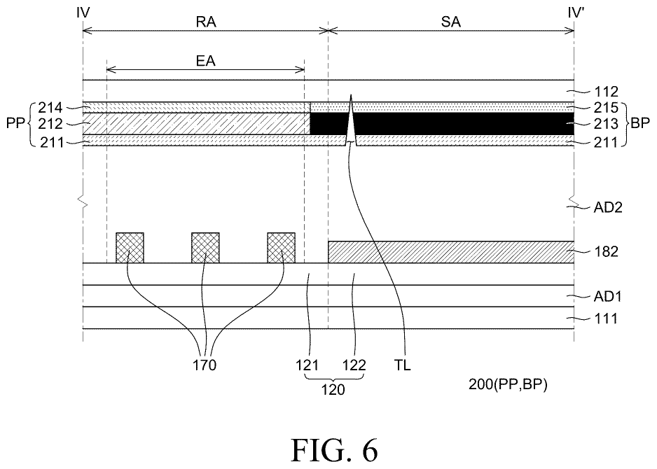

For example, referring to FIG. 4, the polarization pattern PP is formed to have the same size as the rigid area RA so that in the rigid area RA, only the polarization pattern PP can be disposed. For example, referring to FIG. 6, the polarization pattern PP is formed to be smaller than the rigid area RA so that in the rigid area RA, both the polarization pattern PP and the black pattern BP can be disposed. The polarization pattern PP has the same size as the first plate pattern 121. The polarization pattern PP has a size which is larger than the size of the emission area EA and is smaller than the size of the first plate pattern 121.

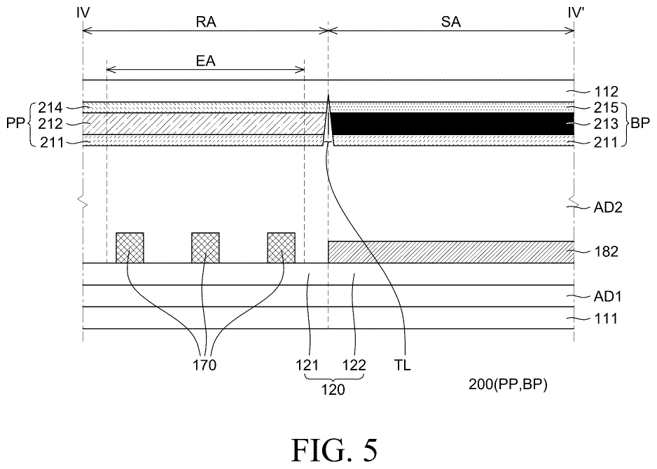

The black pattern BP can be a configuration which serves as a black matrix while reducing the external light reflection. The black pattern BP can be disposed so as to overlap the malleable area SA. In some embodiments, the black pattern BP can be disposed in the malleable area SA, as shown in FIGS. 4 and 5. When the display device 100 is stretched, the black pattern BP disposed in the malleable area SA can be stretched. The black pattern BP can be disposed so as to enclose the plurality of rigid areas RA. The black pattern BP can be formed to have a shape corresponding to the malleable area SA, for example, a mesh shape. The black pattern BP disposed in an area between the plurality of pixels PX can serve as a black matrix. In some embodiments, a part of the black pattern BP can extend from the malleable area SA to the rigid area RA, as shown in FIG. 6.

The tear line TL is a part through which the polarization plate 200 is divided into a plurality of portions and a gap can be formed between the polarization pattern PP and the black pattern BP by the tear line TL. The tear line TL is a cutting part where a portion of the polarization plate 200 is cut. For example, the polarization pattern PP of the rigid area RA can be separated from at least part of the black pattern BP of the malleable area SA by the tear line TL.

The tear line TL can be disposed so as to enclose the polarization pattern PP of the rigid area RA. For example, the tear line TL can be disposed along a periphery of the rigid area RA in the malleable area SA. The tear line TL is located in a boundary of the malleable area SA and the rigid area RA or in the malleable area SA. The tear line TL can be disposed in the boundary of the malleable area SA and the rigid area RA or in the malleable area SA adjacent to the boundary of the malleable area SA and the rigid area RA, depending on the process margin. For example, referring to FIGS. 3, 4, and 6, the tear line TL can be disposed so as to pass through the black pattern BP in the malleable area SA.

Referring to FIG. 5, the tear line TL can be disposed so as to pass through the polarization plate 200 in the boundary of the malleable area SA and the rigid area RA. Referring to FIG. 6, a width of the tear line TL on one surface of the polarization plate 200 is different from a width of the tear line TL on an opposite surface of the one surface of the polarization plate 200.

However, the tear line TL may not be disposed in the rigid area RA. If the tear line TL is disposed in the rigid area RA, various metals located in the rigid area RA may not be blocked and external light reflection and light leakage are caused to degrade the display quality. Further, a part of the polarization pattern PP connected to the black pattern BP of the malleable area SA can be affected by the stretching of the black pattern BP to be deformed and the effect of blocking the external light can be reduced. Accordingly, the tear line TL is disposed in the boundary of the rigid area RA and the malleable area SA or in the malleable area SA to minimize the deformation of the polarization pattern PP and the light leakage caused by the tear line TL.

Further, at least a part of the black pattern BP can be connected to the periphery of the polarization pattern PP according to a size of the polarization pattern PP and a position of the tear line TL. When the tear line TL is located in the malleable area SA or the polarization pattern PP has a size smaller than that of the rigid area RA, the black pattern BP can be connected to an edge of the polarization pattern PP.

For example, as illustrated in FIGS. 3 and 4, when the polarization pattern PP has the same size as the rigid area RA and the tear line TL is located in the malleable area SA, a part of the black pattern BP can be connected to the edge of the polarization pattern PP. For example, the tear line TL is disposed in any one place from the boundary of the rigid area RA and the malleable area SA to the malleable area SA so that as illustrated in FIG. 6, if the polarization pattern PP has a size smaller than that of the rigid area RA, a part of the black pattern BP can be connected to the edge of the polarization pattern PP.

The second adhesive layer AD2 is filled in the tear line TL. The second adhesive layer AD2 is disposed so as to enclose a lower portion and a side portion of the polarization pattern PP to fix the polarization pattern PP. When the display device 100 is stretched, deformation of the polarization pattern PP of the rigid area RA can be minimized by the second adhesive layer AD2 which fixes the polarization pattern PP.

Next, referring to FIGS. 4 to 6, the polarization pattern PP includes a retardation layer 211, a linear polarization layer 212, and an alignment film 214.

The retardation layer 211 is disposed on the second adhesive layer AD2. The retardation layer 211 delays a phase of linearly polarized light which is incident from the outside by passing through the linear polarization layer 212. For example, the retardation layer 211 can be a quarter wave plate (QWP) which delays a phase of the linearly polarized light from the linear polarization layer 212 by 45 degrees. Accordingly, the retardation layer 211 delays the phase of the linearly polarized light to be changed to circularly polarized light.

The linear polarization layer 212 is disposed on the retardation layer 211. The linear polarization layer 212 transmits only light in a specific direction, among light incident from the outside, and absorbs light in the other directions. For example, when natural light is incident to the linear polarization layer 212, only linearly polarized light which vibrates in a specific direction can pass through the linear polarization layer 212. For example, when the linear polarization layer 212 has a transmission axis of 90 degrees, light which vibrates in the direction of the transmission axis passes through the linear polarization layer 212 and light which vibrates in a direction different from the transmission axis may not pass through the linear polarization layer 212.

Therefore, the natural light which is incident to the display device 100 from the outside is linearly polarized by the linear polarization layer 212 and the linearly polarized external light is circularly polarized by the retardation layer 211. Further, the circularly polarized external light is reflected by various components of the display device 100 to be directed to the polarization plate 200 and can be linearly polarized by 0 degree or 180 degrees by the retardation layer 211. However, the external light which is linearly polarized by 0 degree or 180 degrees is light in a direction different from the transmission axis of 90 degrees of the linear polarization layer 212 so that the external light may not pass through the linear polarization layer 212, but can be absorbed by the linear polarization layer 212. Accordingly, the external light which is incident to the display device 100 is suppressed from being re-reflected from an internal configuration of the display device 100, by the polarization plate 200.

The linear polarization layer 212 can include a plurality of dyes. The linear polarization layer 212 can be formed by mixing a reactive mesogen and a dye. The reactive mesogen can include a liquid crystalline polymer, a liquid crystalline small molecule, or an oligomer, having a mesogen which has a photosensitive group exhibiting optical anisotropy and exhibits liquid crystallinity at a specific temperature, or a mixture thereof. The reactive mesogen has a molecular structure similar to the dye and the dye can be aligned in one direction along the reactive mesogen which is aligned in one direction along the alignment film 214. The dye has a dichroic property and can include a black dye or a mixture of red, green, and blue dyes or a mixture of cyan, magenta, and yellow dyes.

The alignment film 214 is disposed on the linear polarization layer 212. The alignment film 214 aligns the dyes of the linear polarization layer 212 in a specific direction. For example, a process, such as rubbing, is performed on resin, such as polyimide to form an alignment film 214 with fine grooves in a specific direction.

Next, the black pattern BP includes a retardation layer 211, a black layer 213, and a non-alignment film 215.

The retardation layer 211 is disposed on the second adhesive layer AD2. The retardation layer 211 of the black pattern BP is substantially the same layer as the retardation layer 211 of the polarization pattern PP. The retardation layer 211 can be configured by a part overlapping the black layer 213 and the other part overlapping the linear polarization layer 212.

The black layer 213 is disposed on the retardation layer 211. The black layer 213 absorbs light incident from the outside. The black layer 213 is configured to absorb natural light incident from the outside to suppress the reflection of external light in the malleable area SA in which the black layer 213 is located. The black layer 213 can improve the black luminosity of the display device 100. The black luminosity indicates a degree of black color of the display device 100 in an off state and the black layer 213 is formed to improve the black luminosity.

The black layer 213 can be formed on the same layer with the same material as the linear polarization layer 212 and for example, can be formed of a mixture of the reactive mesogen and the dye. However, in the black layer 213, dyes are randomly disposed to absorb light in various directions.

The non-alignment film 215 is disposed on the black layer 213. The non-alignment film 215 can be formed on the same layer with the same material as the alignment film 214. However, the non-alignment film 215 has not been subject to a separate rubbing process so that the dyes of the black layer 213 are not aligned in a specific direction, but can be randomly aligned.

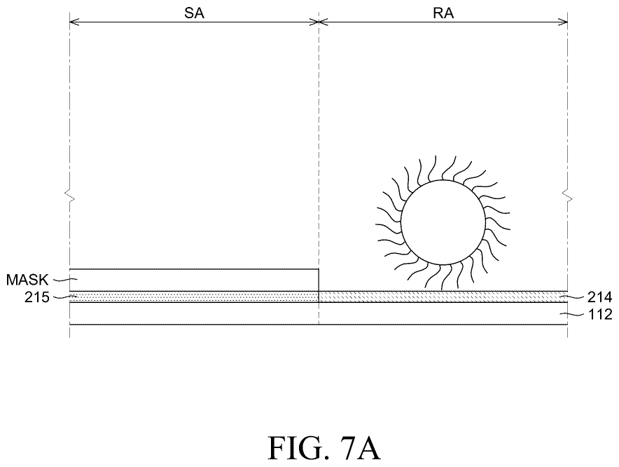

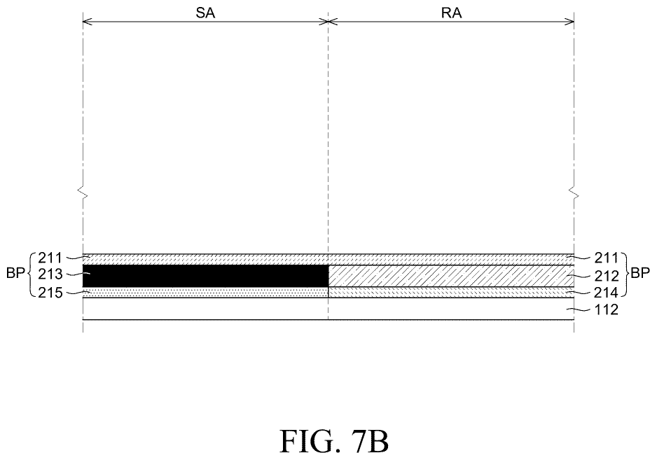

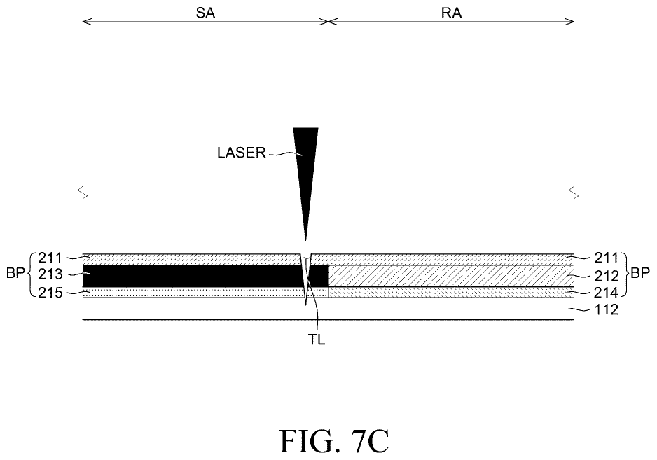

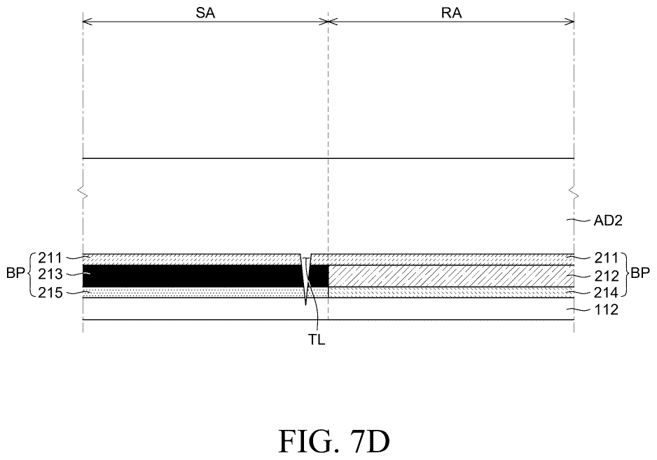

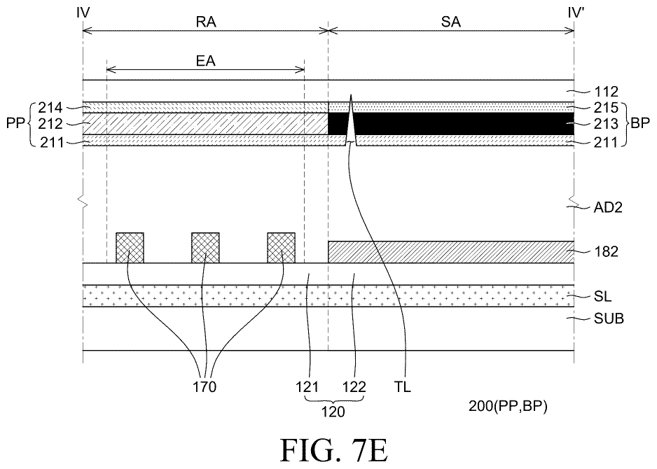

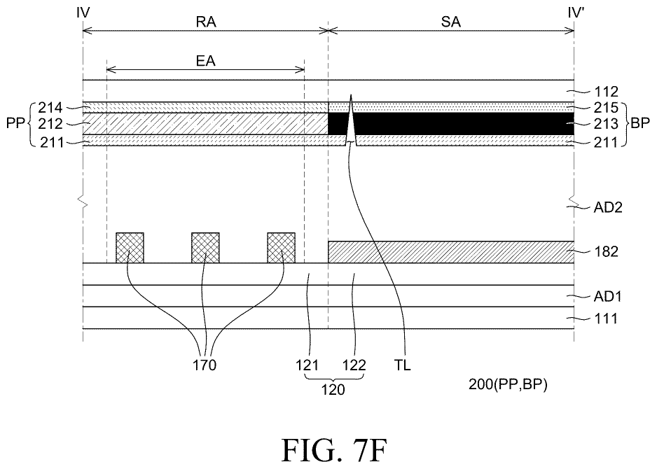

Hereinafter, a manufacturing method of a display device 100 and a polarization plate 200 according to an example embodiment of the present disclosure will be described with reference to FIGS. 7A to 7F.

FIGS. 7A to 7F are process diagrams for explaining a manufacturing method of a display device according to an example embodiment of the present disclosure.

Referring to FIG. 7A, an alignment film 214 and a non-alignment film 215 are formed on the upper substrate 112. Specifically, materials which configure the alignment film 214 and the non-alignment film 215 can be formed on one surface of the upper substrate 112. Further, a mask is disposed on the malleable area SA and the rubbing process is performed only on the remaining part which is not blocked by the mask, for example, on the rigid area RA, to form the alignment film 214 in the rigid area RA and form the non-alignment film 215 in the malleable area SA.

Referring to FIG. 7B, the linear polarization layer 212 and the black layer 213 are formed on the alignment film 214 and the non-alignment film 215 and the retardation layer 211 is formed on the linear polarization layer 212 and the black layer 213. Specifically, a mixture of the reactive mesogen and the dye is coated on the alignment film 214 and the non-alignment film 215. At this time, in the mixture coated on the alignment film 214, the dyes can be aligned in one direction by the alignment film 214 and in the mixture coated on the non-alignment film 215, the dyes can be randomly disposed. Next, the mixture of the reactive mesogen and the dyes are cured to form the linear polarization layer 212 and the black layer 213. After completing the formation of the linear polarization layer 212 and the black layer 213, the retardation layer 211 can be formed on the linear polarization layer 212 and the black layer 213.

Referring to FIG. 7C, the tear line TL is formed in the polarization plate 200. Specifically, the tear line TL can be formed by irradiating laser in the boundary of the rigid area RA and the malleable area SA or in the malleable area SA adjacent to the periphery of the rigid area RA.

At this time, the tear line TL passes through the polarization plate 200 to be formed to reach the upper substrate 112. A depth of the tear line TL is larger than the thickness of the polarization plate 200 and is smaller than a sum of the thicknesses of the polarization plate 200 and the upper substrate 112. When the tear line TL is formed, the intensity of the laser can be controlled so as not to completely cut the upper substrate 112, but to cut only a minimum part of the upper substrate 112.

Further, the laser for forming the tear line TL is irradiated from the retardation layer 211 toward the upper substrate 112 so that the tear line TL extends from the retardation layer 211 (or the polarization plate 200) to one surface of the upper substrate 112 and the tear line TL has a width which is narrowed from the retardation layer 211 (or the polarization plate 200) toward the upper substrate 112. Specifically, the width of the tear line TL is the largest in the retardation layer 211 and the width of the tear line TL is gradually reduced toward the upper substrate 112. The tear line TL has a V-shaped cross-sectional shape which is narrowed from the retardation layer 211 toward the upper substrate 112. In the meantime, even though in the drawings, the tear line TL has a V-shaped cross-section, the tear line can have an U-shaped cross-section or an I-shaped cross-section depending on the type of the laser, but is not limited thereto.

Referring to FIG. 7D, the second adhesive layer AD2 is formed on the polarization plate 200. The second adhesive layer AD2 can be formed on the retardation layer 211 of the polarization plate 200 and the second adhesive layer AD2 can be filled in the tear line TL.

Referring to FIG. 7E, the pattern layer 120 on which the plurality of light emitting diodes 170 and the connection line 180 are formed is bonded to the upper substrate 112, the polarization plate 200, and the second adhesive layer AD2.

The pattern layer 120 on a temporary substrate SUB and the second adhesive layer AD2 on the upper substrate 112 are disposed to be opposite to each other to bond the temporary substrate SUB and the upper substrate 112. Accordingly, the temporary substrate SUB on which the pattern layer 120, the light emitting diode 170, and the connection line 180 are formed and the upper substrate 112 on which the polarization plate 200 is formed can be bonded by the second adhesive layer AD2.

The temporary substrate SUB is a member which supports the pattern layer 120 and components disposed on the pattern layer 120 during the manufacturing process of the display device 100. The temporary substrate SUB can be formed of a material having a rigidity. For example, the temporary substrate SUB can be formed of glass, but is not limited thereto.

A sacrificial layer SL is a layer formed to easily separate the temporary substrate SUB and the pattern layer 120 from each other, as shown in FIG. 7E. Laser is irradiated to the sacrificial layer SL from the lower portion of the temporary substrate SUB to dehydrogenate the sacrificial layer SL and separate the temporary substrate SUB and the sacrificial layer SL from the pattern layer 120. For example, the sacrificial layer SL can use hydrogenated amorphous silicon or amorphous silicon which is hydrogenated and doped with impurities.

The sacrificial layer SL is formed on the temporary substrate SUB and a process of forming the pattern layer 120 and the plurality of pixels PX is performed on the sacrificial layer SL. The pattern layer 120 is formed on the sacrificial layer SL and a plurality of circuits, a plurality of wiring lines, and a plurality of connection lines 180 can be formed on the pattern layer 120. Further, the plurality of light emitting diodes 170 is transferred onto the plurality of first plate patterns 121 of the pattern layer 120 to form the plurality of sub pixels SPX.

Finally, referring to FIG. 7F, the temporary substrate SUB is removed and the lower substrate 111 is bonded. The laser is irradiated to the sacrificial layer SL from the outside of the temporary substrate SUB to separate the temporary substrate SUB and the pattern layer 120. Further, the lower substrate 111 can be bonded on one surface of the pattern layer 120 using the first adhesive layer AD1.

Accordingly, in the manufacturing method of the display device 100 and the polarization plate 200 according to the example embodiment of the present disclosure, the polarization plate 200 is formed on one surface of the upper substrate 112 and the upper substrate 112 and the polarization plate 200 are bonded onto the lower substrate 111. By doing this, the display device 100 including the polarization plate 200 can be formed. For example, the display device 100 can be formed by a roll-to-roll manner which forms the alignment film 214, the linear polarization layer 212, and the retardation layer 211 directly on the upper substrate 112 and bonding the upper substrate 112 attached with the polarization plate 200 to the lower substrate 111. Therefore, the manufacturing method of the display device 100 and the polarization plate 200 according to the example embodiment of the present disclosure is advantageous to produce a large amount of display devices 100. Further, according to this manufacturing method, an adhesive layer for bonding the polarization plate 200 and the upper substrate 112 is omitted to save the manufacturing cost.

In the display device 100 according to the example embodiment of the present disclosure, the polarization plate 200 includes a polarization pattern PP and the black pattern BP together to improve the black luminosity while reducing the external light reflection. In the rigid area RA which is not stretched, the polarization pattern PP in which the dyes are aligned in one direction is formed to suppress the reflection of the external light and the image is displayed by the plurality of sub pixels SPX. Further, in the malleable area SA which is stretched, the black layer 213 is disposed to absorb the external light. At this time, even though the black layer 213 in which the dyes are randomly disposed is stretched, the black layer 213 can absorb light and implements black in the malleable area SA in which the sub pixel SPX is not disposed to improve the black luminosity of the display device 100. In contrast, the polarization pattern PP in which the dyes are aligned in a predetermined direction is disposed in the rigid area RA which is not stretched to suppress the deformation. Accordingly, in consideration of the characteristic of the rigid area RA and the malleable area SA, the polarization pattern PP is disposed in the rigid area RA and the black layer 213 is disposed in the malleable area SA to minimize the external light reflection and improve the black luminosity.

In the display device 100 according to the example embodiment of the present disclosure, the tear line TL which separates the polarization pattern PP from the black pattern BP is formed to minimize the deformation of the polarization pattern PP. The black pattern BP is disposed in the malleable area SA to be stretched together when the display device 100 is stretched. In the polarization plate 200, the tear line TL which separates the black pattern BP of the malleable area SA and the polarization pattern PP of the rigid area RA is formed so as not to allow the polarization pattern PP to be affected by the stretching of the black pattern BP. Accordingly, the tear line TL is formed between the polarization pattern PP and the black pattern BP to minimize the deformation of the polarization pattern PP by the black pattern BP.

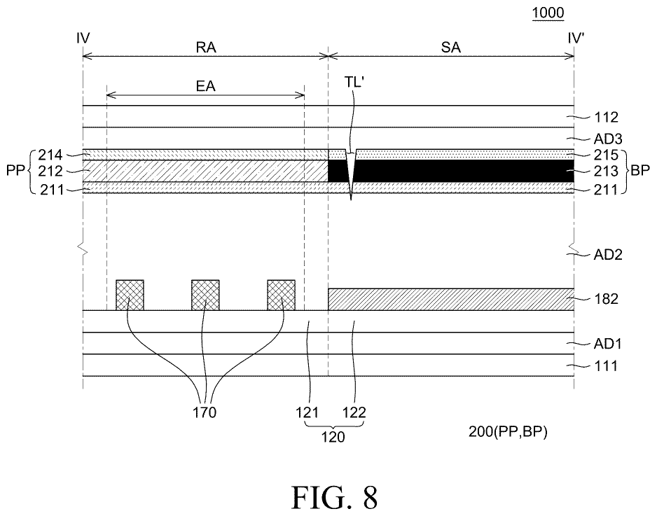

FIG. 8 is a schematic cross-sectional view of a display device according to another example embodiment of the present disclosure. As compared with the display device 100 of FIG. 1 to FIG. 6, a display device 1000 of FIG. 8 further includes a third adhesive layer AD3 and a tear line TL′ is different, but the other configurations are substantially the same, so that a redundant description will be omitted or may be briefly provided.

Referring to FIG. 8, a third adhesive layer AD3 can be disposed between the polarization plate 200 and the upper substrate 112. A display device 1000 is formed by forming the polarization plate 200 on a separate temporary substrate SUB and then bonding them onto the second adhesive layer AD2 so that a third adhesive layer AD3 can be further disposed to bond the polarization plate 200 and the upper substrate 112.

The tear line TL′ can have a cross-sectional shape which is narrowed from the linear polarization layer 212 toward the retardation layer 211. Similar to the tear line TL shown in FIG. 6, the width of the tear line TL′ on one surface of the polarization plate 200 is different from the width of the tear line TL′ on an opposite surface of the one surface of the polarization plate 200. Further, a depth of the tear line TL′ can be larger than a thickness of the polarization plate 200. Accordingly, the tear line TL′ can be formed so as to reach the second adhesive layer AD2.

Further, the third adhesive layer AD3 is disposed to be filled in the tear line TL′. The third adhesive layer AD3 can be disposed to be filled in the tear line TL′ to enclose an upper portion and a side portion of the polarization pattern PP.

Hereinafter, a manufacturing method of a display device 1000 and a polarization plate 200 according to an example embodiment of the present disclosure will be described.

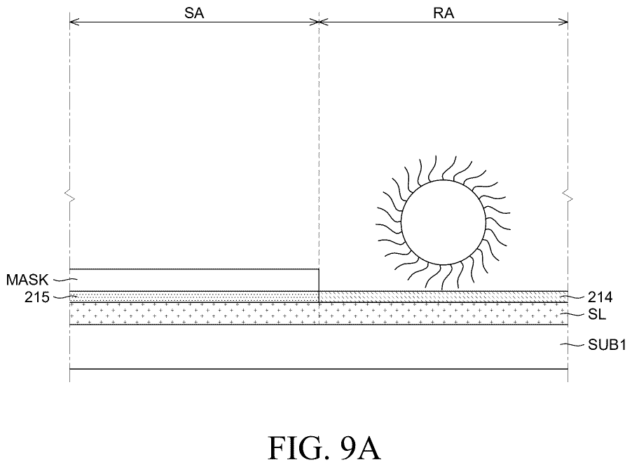

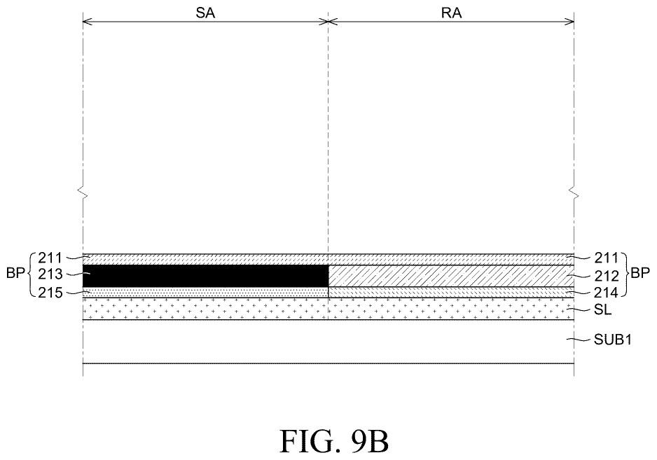

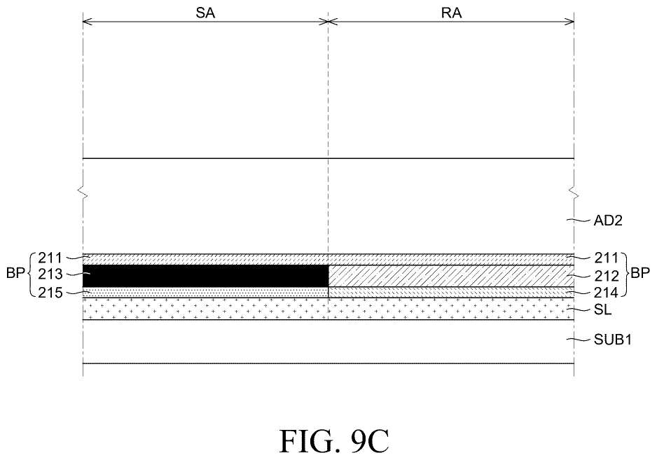

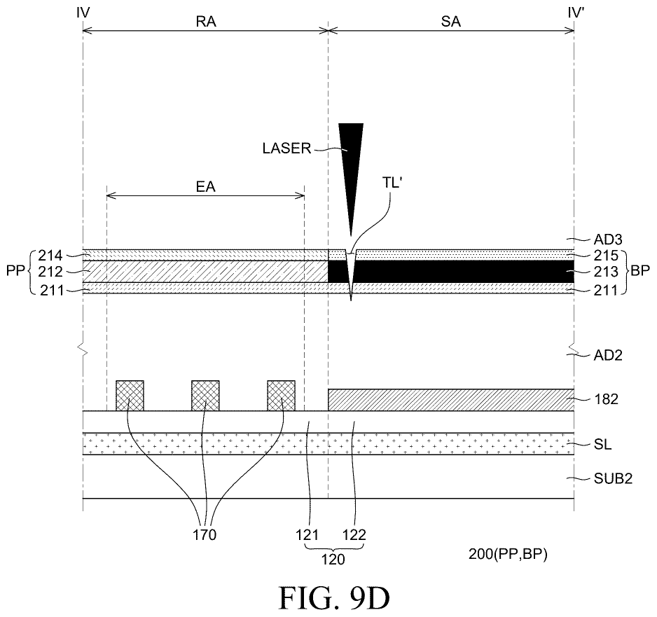

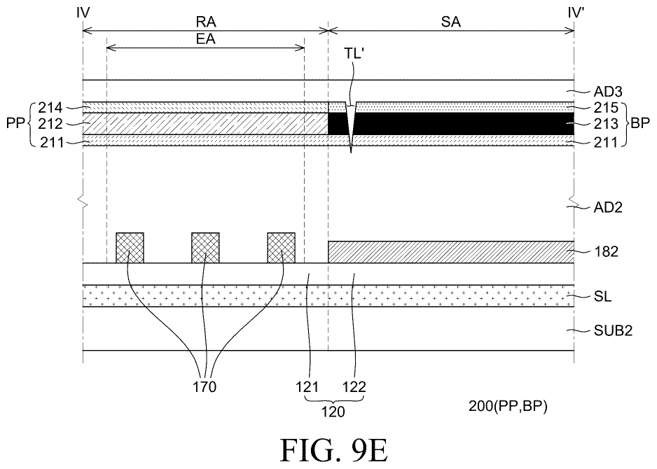

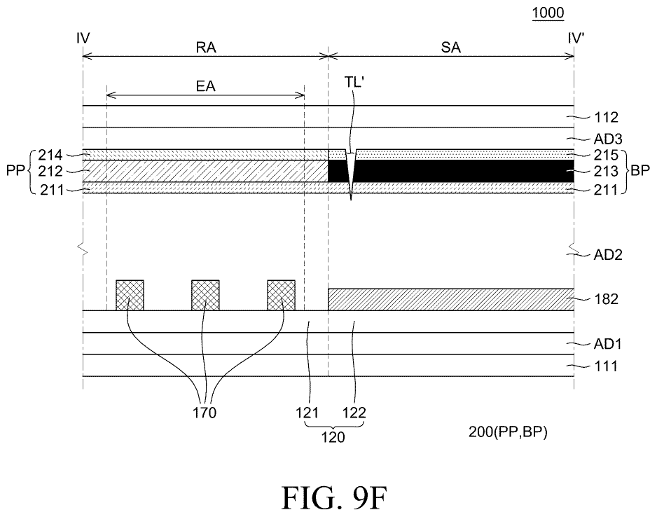

FIGS. 9A to 9F are process diagrams for explaining a manufacturing method of a display device according to another example embodiment of the present disclosure.

Referring to FIG. 9A, an alignment film 214 and a non-alignment film 215 are formed on a first temporary substrate SUB1. A sacrificial layer SL is formed on the first temporary substrate SUB1 and materials for forming the alignment film 214 and the non-alignment film 215 can be formed on the sacrificial layer SL. Further, a mask is disposed in the malleable area SA and a rubbing process is performed only in the rigid area RA which is exposed from the mask to form the alignment film 214.

Referring to FIG. 9B, the linear polarization layer 212 and the black layer 213 are formed on the alignment film 214 and the non-alignment film 215 and the retardation layer 211 is formed on the linear polarization layer 212 and the black layer 213. A mixture of dyes and a reactive mesogen is coated on the alignment film 214 and the non-alignment film 215 and is cured to form the linear polarization layer 212 and the black layer 213. Further, a material for forming the retardation layer 211 is coated on the linear polarization layer 212 and the black layer 213 or the retardation layer 211 can be attached thereto.

Referring to FIGS. 9C and 9D, the second adhesive layer AD2 is formed on the retardation layer 211 to bond the first temporary substrate SUB1 and the second temporary substrate SUB2. First, the second adhesive layer AD2 can be formed on the first temporary substrate SUB1 on which the polarization plate 200 is formed. Further, the first temporary substrate SUB1 on which the polarization plate 200 is formed can be bonded to the second temporary substrate SUB2 on which the pattern layer 120, the connection line 180, and the plurality of light emitting diodes 170 are formed using the second adhesive layer AD2.

Next, the first temporary substrate SUB1 is separated from the polarization plate 200 and the tear line TL′ is formed in the polarization plate 200. Specifically, the laser is irradiated to the first temporary substrate SUB1 to separate the first temporary substrate SUB1 from the polarization plate 200. Further, the laser is irradiated to the polarization plate 200 exposed from the first temporary substrate SUB1 to form the tear line TL′.

A depth of the tear line TL′ can be larger than a thickness of the polarization plate 200. Accordingly, the tear line TL′ can be formed so as to reach a part of the second adhesive layer AD2 which is in contact with the polarization plate 200.

Further, when the tear line TL′ is formed, the laser is irradiated to one surface of the non-alignment film 215 and the alignment film 214 so that the tear line TL′ extends from the polarization plate 200 to one surface of the second adhesive layer AD2 and the tear line TL′ has a width which is narrowed from the polarization plate 200 toward the second adhesive layer AD2. Specifically, the tear line TL′ can have a width which is narrowed from the non-alignment film 215 toward the retardation layer 211.

Referring to FIG. 9E, the upper substrate 112 is bonded to the polarization plate 200 using the third adhesive layer AD3. The third adhesive layer AD3 can be formed on the polarization plate 200. The third adhesive layer AD3 can be disposed so as to be in filled in the tear line TL′ while covering one surface of the polarization plate 200. Further, the upper substrate 112 can be attached onto the third adhesive layer AD3.

Finally, referring to FIG. 9F, the second temporary substrate SUB2 is removed and the lower substrate 111 is bonded to the pattern layer 120 using the first adhesive layer AD1. The laser is irradiated to the second temporary substrate SUB2 to separate the second temporary substrate SUB2 from the pattern layer 120. Further, the lower substrate 111 can be bonded below the pattern layer 120 using the first adhesive layer AD1.

Accordingly, in the manufacturing method of the display device 1000 and the polarization plate 200 according to another example embodiment of the present disclosure, after forming the polarization plate 200 on the first temporary substrate SUB1, the polarization plate 200 is bonded to the lower substrate 111 and the upper substrate 112 to form the display device 1000. For example, the first temporary substrate SUB1 on which the polarization plate 200 is formed is bonded to the second temporary substrate SUB2 on which the pattern layer 120 and the plurality of pixels PX are formed. Thereafter, the display device 1000 including the polarization plate 200 is formed by a cell-to-cell manner which separates the first temporary substrate SUB1 and the second temporary substrate SUB2 and attaching the lower substrate 111 and the upper substrate 112. At this time, in the state in which the polarization plate 200 is bonded onto the pattern layer 120, the tear line TL′ is formed so that the formation area of the tear line TL′ can be more precisely controlled. Further, the first temporary substrate SUB1 and the second temporary substrate SUB2 are precisely aligned to minimize an alignment error of the polarization plate 200 and the pattern layer 120. Accordingly, in the manufacturing method of the display device 1000 and the polarization plate 200 according to another example embodiment of the present disclosure, a position of the tear line TL′ and a bonding position of the polarization plate 200 and the pattern layer 120 are precisely adjusted. Therefore, a high resolution display device 1000 can be easily formed and achieved.

The example embodiments of the present disclosure can also be described as follows:

According to an aspect of the present disclosure, a display device includes a lower substrate which includes a plurality of rigid areas and a malleable area enclosing each of the plurality of rigid areas, a plurality of first plate patterns disposed in the plurality of rigid areas of the lower substrate, a plurality of light emitting diodes disposed on the plurality of first plate patterns, and a polarization plate which is disposed on the plurality of light emitting diodes and includes a plurality of polarization patterns and a black pattern which encloses the plurality of polarization patterns, and the plurality of polarization patterns overlaps the plurality of rigid areas and the black pattern overlaps the malleable area.

Each of the plurality of first plate patterns can include an emission area in which the plurality of light emitting diodes is disposed and each of the plurality of polarization patterns can be disposed so as to overlap at least the emission area in each of the plurality of first plate patterns.

Each of the plurality of polarization patterns can have the same size as each of the plurality of first plate patterns.

Each of the plurality of polarization patterns can have a size which is larger than the size of the emission area and is smaller than the size of each of the plurality of first plate patterns and a part of the black pattern extends from the malleable area to the rigid area. Each of the plurality of polarization patterns can include a retardation layer, a linear polarization layer on the retardation layer, and an alignment film on the linear polarization layer, and the black pattern can include a retardation layer, a black layer on the retardation layer, and a non-alignment film on the black layer, and the retardation layer of each of the plurality of polarization patterns can be formed on the same layer with the same material as the retardation layer of the black pattern.

The linear polarization layer and the black layer can include a plurality of dyes and the plurality of dyes of the linear polarization layer can be aligned in one direction and the plurality of dyes of the black layer can be randomly aligned.

The linear polarization layer and the black layer can be disposed on the same layer and the alignment film and the non-alignment film are disposed on the same layer.

The polarization plate can further include a tear line which is disposed so as to pass through the polarization plate and the tear line can be configured to separate the plurality of polarization patterns of the rigid area from at least part of the black pattern of the malleable area.

The tear line can be disposed in a boundary of the plurality of polarization patterns and the black pattern.

The tear line can be configured so as to pass through the black pattern.

A width of the tear line on one surface of the polarization plate can be different from a width of the tear line on an opposite surface of the one surface of the polarization plate.

A depth of the tear line can be larger than a thickness of the polarization plate.

The display device can further include a first adhesive layer disposed between the lower substrate and the plurality of first plate patterns, a second adhesive layer disposed between the plurality of first plate patterns and the polarization plate, and an upper substrate disposed on the polarization plate, and the tear line can extend from the polarization plate to one surface of the upper substrate and the tear line can have a width which is narrowed from the polarization plate toward the upper substrate.

The second adhesive layer can be configured to be filled in the tear line.

The display device can further include a first adhesive layer disposed between the lower substrate and the plurality of first plate patterns, a second adhesive layer disposed between the plurality of first plate patterns and the polarization plate, a third adhesive layer disposed on the polarization plate, and an upper substrate disposed on the third adhesive layer, and the tear line can extend from the polarization plate to one surface of the second adhesive layer and the tear line can have a width which is narrowed from the polarization plate toward the second adhesive layer.

The third adhesive layer can be configured to be filled in the tear line.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a lower substrate including a plurality of rigid areas and a malleable area enclosing each of the plurality of rigid areas;
a plurality of first plate patterns disposed in the plurality of rigid areas of the lower substrate;
a plurality of light emitting diodes disposed on the plurality of first plate patterns; and
a polarization plate disposed on the plurality of light emitting diodes, and including a plurality of polarization patterns and a black pattern enclosing the plurality of polarization patterns,
wherein the plurality of polarization patterns overlaps the plurality of rigid areas and the black pattern overlaps the malleable area.

2. The display device according to claim 1, wherein each of the plurality of first plate patterns includes an emission area in which the plurality of light emitting diodes is disposed, and
wherein each of the plurality of polarization patterns is disposed so as to overlap at least the emission area in each of the plurality of first plate patterns.

3. The display device according to claim 1, wherein each of the plurality of polarization patterns has a same size as each of the plurality of first plate patterns.

4. The display device according to claim 2, wherein each of the plurality of polarization patterns has a size, which is larger than a size of the emission area and is smaller than a size of each of the plurality of first plate patterns, and
wherein a part of the black pattern extends from the malleable area to the rigid area.

5. The display device according to claim 1, wherein each of the plurality of polarization patterns includes:
a retardation layer;
a linear polarization layer on the retardation layer; and
an alignment film on the linear polarization layer.

6. The display device according to claim 5, wherein the black pattern includes:
another retardation layer;
a black layer on the another retardation layer; and
a non-alignment film on the black layer, and
the retardation layer of each of the plurality of polarization patterns is formed on a same layer with a same material as the another retardation layer of the black pattern.

7. The display device according to claim 6, wherein the linear polarization layer and the black layer include a plurality of dyes, and the plurality of dyes of the linear polarization layer is aligned in one direction and the plurality of dyes of the black layer is randomly aligned.

8. The display device according to claim 6, wherein the linear polarization layer and the black layer are disposed on a same layer, and the alignment film and the non-alignment film are disposed on a same layer.

9. The display device according to claim 6, wherein the polarization plate further includes a tear line disposed to pass through the polarization plate, and the tear line is configured to separate the plurality of polarization patterns of the rigid area from at least part of the black pattern of the malleable area.

10. The display device according to claim 9, wherein the tear line is disposed in a boundary of the plurality of polarization patterns and the black pattern.

11. The display device according to claim 9, wherein the tear line is configured to pass through the black pattern.

12. The display device according to claim 9, wherein a width of the tear line on one surface of the polarization plate is different from a width of the tear line on an opposite surface of the one surface of the polarization plate.

13. The display device according to claim 9, wherein a depth of the tear line is larger than a thickness of the polarization plate.

14. The display device according to claim 13, further comprising:
a first adhesive layer disposed between the lower substrate and the plurality of first plate patterns;
a second adhesive layer disposed between the plurality of first plate patterns and the polarization plate; and
an upper substrate disposed on the polarization plate,
wherein the tear line extends from the polarization plate to one surface of the upper substrate, and the tear line has a width which is narrowed from the polarization plate toward the upper substrate.

15. The display device according to claim 14, wherein the second adhesive layer is configured to be filled in the tear line.

16. The display device according to claim 13, further comprising:
a first adhesive layer disposed between the lower substrate and the plurality of first plate patterns;
a second adhesive layer disposed between the first plate patterns and the polarization plate;
a third adhesive layer disposed on the polarization plate; and
an upper substrate disposed on the third adhesive layer,
wherein the tear line extends from the polarization plate to one surface of the second adhesive layer, and the tear line has a width which is narrowed from the polarization plate toward the second adhesive layer.

17. The display device according to claim 16, wherein the third adhesive layer is configured to be filled in the tear line.
